(19) United States
(12) Patent Application Publication
(10) Pub. No.: US 2008/0119040 A1
(43) Pub. Date: May 22, 2008

(54) Method for forming a dual damascene structure

(75) Inventors: Chih-Han Lin, Tainan (TW); Chien-Chung Chen, Kaohsiung (TW); K.T. Lai, Hsinchu (TW); Hung-Lung Hu, Tainan (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/602,344

(22) Filed: Nov. 21, 2006

(51) Int. Cl. H01L 21/768

(52) U.S. Cl. 438/636; 438/637; 257/E21.579; 257/E21.587

(57) ABSTRACT

A method for forming a dual damascene structure is provided. In one embodiment, a semiconductor substrate with a patterned protective layer formed thereover is provided. A conformal dielectric layer is formed over the protective layer. A patterned mask layer is formed over the dielectric layer. A portion of the dielectric layer is etched substantially up to about the top surface of the protective layer according to the pattern of the mask layer to form a trench. The protective layer is then removed to form a via hole. A conductive layer is formed in the via hole and the trench, thereby forming a dual damascene structure.

### BACKGROUND

The present disclosure relates generally to the manufacturing of semiconductor devices, and more particularly to a damascene process utilized in semiconductor manufacturing.

With increased device density, the available area for circuit wiring becomes a potential limiting factor in device performance. Such a limitation has led to the development of multi-layer wiring and the adoption of damascene and dual-damascene structures. During a damascene process, interconnect metal lines are delineated in dielectric and isolated from each other by planarization. First, an interconnect pattern is lithographically defined in the layer of dielectric. Then, metal is deposited to fill resulting trenches, and excessive metal is removed by chemical mechanical polishing planarization.

A dual-damascene process is a modified version of the damascene process. It is used to form metal interconnect geometry using planarization such as chemical mechanical polishing. Generally, dual damascene technology includes: a via-first dual damascene process or a trench-first dual damascene process. For the via-first process, a via hole is first formed in a dielectric layer and on an etch stop layer covering a metal layer, and then a process for forming a trench is applied so as to form a via hole and trench structure. A conductive layer then is filled into the via hole and trench structure. A dual damascene structure is thus finished. In contrast, the trench-first process forms a trench in a dielectric layer, and then a process for defining a via hole is applied.

These conventional dual damascene sequences introduce a high number of processing steps resulting in high process and tool costs. Further, the dual damascene structure formed by these steps exhibit poor RC (resistance capacitance) metal interconnect properties and high K values compromising device performance.

For these reasons and other reasons that will become apparent upon reading the following detailed description, there is a need for an improved method of forming dual damascene structures that avoids the shortcomings associated with conventional methods of forming dual damascene structures.

### SUMMARY

The present invention is directed to a method for forming a dual damascene structure. In one embodiment, a semiconductor substrate with a patterned protective layer formed thereover is provided. A conformal dielectric layer is formed over the protective layer. A patterned mask layer is formed over the dielectric layer. A portion of the dielectric layer is etched substantially up to about the top surface of the protective layer according to the pattern of the mask layer to form a trench. The protective layer is then removed to form a via hole. A conductive layer is formed in the via hole and the trench, thereby forming a dual damascene structure.

### BRIEF DESCRIPTION OF THE DRAWINGS

The features, aspects, and advantages of the present invention will become more fully apparent from the following detailed description, appended claims, and accompanying drawings in which:

FIG. 1 is a schematic cross-sectional view of a portion of a semiconductor wafer at stages in a manufacturing process to form a damascene structure showing a patterned protective feature formed on a substrate according to one embodiment of the present invention.

FIG. 2 is a schematic cross-sectional view of the structure of FIG. 1 showing a conformal dielectric layer formed over the protective layer and an anti-reflective coating (ARC) layer formed over the dielectric layer according to one embodiment of the present invention.

FIG. 3 is a schematic cross-sectional view of the structure of FIG. 2 showing a patterned mask layer formed over the ARC layer according to one embodiment of the present invention.

FIG. 4 is a schematic cross-sectional view of the structure of FIG. 3 showing the etching of portions of the ARC layer and the dielectric layer up to about the top surface of the protective layer according to the pattern of the mask layer to form a trench according to one embodiment of the present invention.

FIG. 5 is a schematic cross-sectional view of the structure of FIG. 4 showing the removal of the mask layer, protective layer and a portion of the etch stop layer to form a via hole according to one embodiment of the present invention.

FIG. 6 is a schematic cross-sectional view of the structure of FIG. 5 showing a conductive layer formed in the via hole and the trench, thereby forming a dual damascene structure according to one embodiment of the present invention.

FIG. 7 is a flow chart of a method for forming a dual damascene structure according to one aspect of the present invention.

### DETAILED DESCRIPTION

In the following description, numerous specific details are set forth to provide a thorough understanding of the present invention. However, one having an ordinary skill in the art will recognize that the invention can be practiced without these specific details. In some instances, well-known structures and processes have not been described in detail to avoid unnecessarily obscuring the present invention.

Although the method of the present invention is explained by exemplary reference to the formation of a dual damascene structure in a multi-level semiconductor device it will be appreciated that the method of the present invention is equally applicable to other methods of dual or single damascene structure formation.

Reference will now be made in detail to the present embodiments of the present invention, examples of which are illustrated in the accompanying drawings.

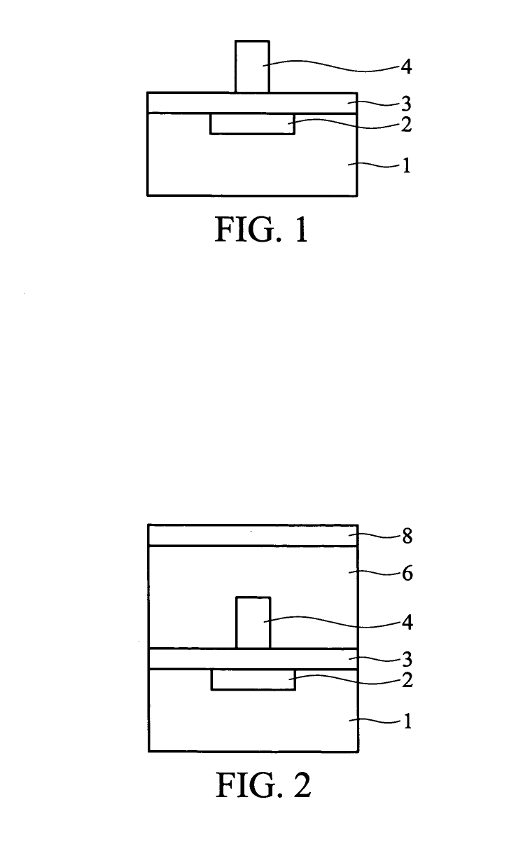

FIG. 1 is a cross-sectional view of a semiconductor wafer at stages in a manufacturing process to form a damascene structure showing a semiconductor substrate 1 having a metal layer 2 formed therein, an etch stop layer 3 formed over the metal layer 2, and a patterned protective layer 4 formed over the etch stop layer 3, according to one embodiment of the present invention. Metal layer 2 may include copper (Cu), aluminum (Al), and/or other conductive materials. Stop or etch stop layer 3 protects the underlying layer and may include materials such as silicon nitride (SiₓN_{y}), silicon oxy-nitride (SiON), silicon carbide (SiC), silicon oxy-carbide (SiOC), silicon dioxide (SiO₂), thermal oxide, tetraethylorthosilicate (TEOS) oxide and/or other materials. Stop layer 3 is formed by a conventional chemical vapor deposition (CVD) process including for example, PECVD (plasma enhanced CVD), LPCVD (low pressure CVD), or HDPCVD (high density plasma CVD) having a thickness of about 200 Angstroms to about 1000 Angstroms.

Following formation of the stop layer 3, a protective layer is formed thereover and thereafter patterned by conventional photolithography processes to form patterned protective layer 4. In various exemplary embodiments, patterned protective layer 4 may include one or more layers comprising polymer, resin, photoresist, positive photoresist, negative photoresist, silicon, polysilicon, silicon dioxide (SiO₂), tetraethylorthosilicate (TEOS) oxide, silicon nitride (SiₓN_{y}), borophosphosilicate glass (BPSG), fluoride-doped silicate glass (FSG), low-k dielectric, and/or other materials. The protective layer 4 may be formed by selective epitaxial growth (SEG), CVD, PECVD, ALD, PVD, electrophoresis, spin-on coating, chemical mechanical polishing or chemical mechanical planarization, and/or other processing techniques. One skilled in the art will understand that protective layer 4 has sufficient thickness to form and function as a plug. In one embodiment of the present invention, the protective layer has a thickness of from about 10 A to about 8000 A. In one aspect of the present invention, the etch selectivity of the protective layer 4 is different than the etch selectivity of a to-be-deposited dielectric layer formed thereover. In another aspect of the present invention, the protective layer 4 has a low etching rate compared to a dielectric material. Various compounds may be added to the protective layer 4 to adjust its etch selectivity.

With reference now to FIG. 2, a cross-sectional view of the structure of FIG. 1 shows a conformal dielectric layer 6 formed over the protective layer 4 and an anti-reflective coating (ARC) layer 8 formed over the dielectric layer 6 according to one embodiment of the present invention. Dielectric layer 6 may be an oxide, a low-k dielectric film, or any of various suitable dielectric materials used in the formation of semiconductor devices. Preferably, the dielectric insulating layer has a dielectric constant less than about 3.2. For example, dielectric layer 6 may include one or more insulative layers such as hydrogen silsesquioxane, methyl silsesquioxane, Black Diamond® (a product of Applied Materials of Santa Clara, Calif.), fluorinated silicaglass, phosphosilicate glass, poly-tetrafluoroethylene, benzocyclobutene, poly-tetra-fluoro-ethylene, Xerogel, Aerogel, amorphous fluorinated carbon, Parylene, BCB (bis-benzocyclobuteness), and SiLK™ (a product of Dow Chemical of Midland, Mich.), and/or other materials. The insulative dielectric layer 6 may be formed by chemical vapor deposition (CVD), plasma enhanced chemical vapor deposition (PECVD), atomic layer deposition (ALD), pulsed deposition layering (PLD), spin-on coating, and/or other processing techniques and thereafter planarized by chemical mechanical polishing. In one embodiment, the dielectric layer 6 is formed having a thickness of about 3000 to about 10,000 Angstroms.

Formed over dielectric layer 6 is an optional liner layer. The liner layer may be a bottom anti-reflective coating (BARC) or anti-reflective coating (ARC) layer 8. The ARC layer is commonly applied between the dielectric layer and the photoresist to reduce undesirable reflections during the photolithographic process. ARC layer 8 may be formed of inorganic materials such as for example SiON, SiOC, SiN, TaN or any of various other suitable materials that may be used as anti-reflective coatings and/or hard masks. ARC layer 8 may be formed over the dielectric layer 6 by a conventional plasma enhanced CVD process, for example, LPCVD, to a thickness of about 200 Angstroms to about 800 Angstroms. The inclusion of the anti-reflective coating layer depends on the condition of the photolithographic process. One of ordinary skill in the art will understand that the formation of the anti-reflective coating layer depends on the conditions of the photolithographic process.

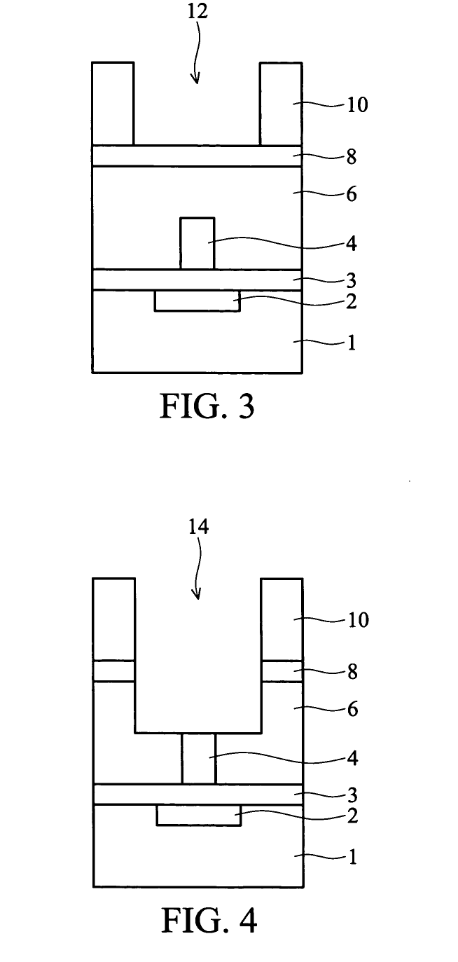

Referring now to FIG. 3, a cross-sectional view of the structure of FIG. 2 shows a patterned mask layer 10 having an opening 12 formed over the ARC layer 8 according to one embodiment of the present invention. A layer of photoresist is deposited on ARC layer 8 by conventional methods and thereafter patterned by conventional photolithographic processes to form patterned mask or photoresist layer 10. Various suitable photoresists are conventionally available and may be used. Opening 12 in patterned mask layer 10 may be adapted for forming trenches, via holes, contacts, and/or other patterned features.

An etching process is then carried out to form dual damascene openings. As shown in FIG. 4, a cross-sectional view of the structure of FIG. 3 shows the etching of portions of the ARC layer 8 and the dielectric layer 6 substantially up to about the top surface of the protective layer 4 according to the pattern of the mask layer 10 to form a trench opening 14 according to one embodiment of the present invention. Various suitable etching methods are available in the art and may be used to etch portions of the ARC layer 8 and dielectric layer 6 such as dry etching, wet etching, or chemical etching. For example, trench opening 14 may be formed in a plasma environment having reactant gases such as hydrochloric acid (HCL), hydrogen bromide (HBr), sulfur dioxide (SO₂), sulfur hexafluoride (SF₆), and/or other reactants. Alternatively, trench opening 14 may be formed by chemical etch which may include an environment having phosphoric acid (H3PO ammonium hydroxide (NH₄OH), hydrochloric acid (HF), sulfuric acid (H₂SO₄), and/or other chemicals.

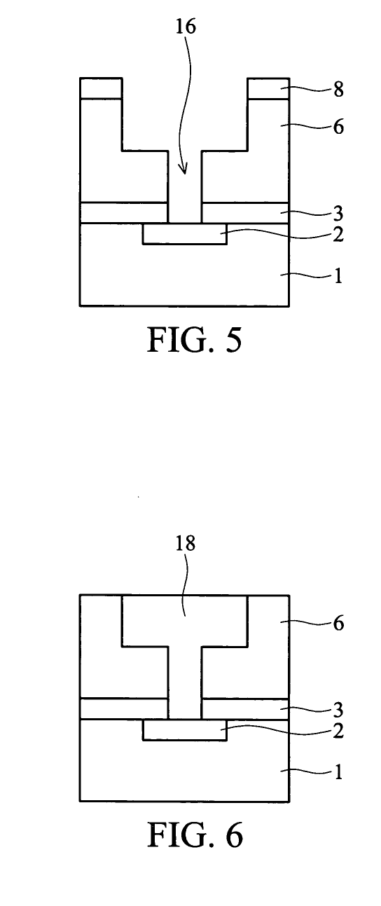

Following the etching process, the photoresist layer or mask layer 10 is stripped using conventional removal methods such as, for example oxygen ashing. Thereafter, the protective layer 4 is removed to form a via hole 16 and a portion of the etch stop layer 3 is removed as shown in FIG. 5. The protective layer 4 may be removed by plasma etch, chemical etch, thermal burn-out, and/or other processing techniques. For example, the protective layer 4 may be removed by an oxygen (O₂) containing plasma environment. The protective layer 4 may also be removed by a plasma environment which may include reactant gases such as hydrochloric acid (HCL), hydrogen bromide (HBr), sulfur dioxide (SO₂), Chlorine (Cl₂), sulfur hexafluoride (SF₆), perfluorocarbons, and/or other reactants. Alternatively, the protective layer 4 may be removed by chemical etch which may include phosphoric acid (H₃PO₄), ammonium hydroxide (NH₄OH), hydrochloric acid (HCL), hydrofluoric acid (HF), sulfuric acid (H₂SO₄), hydrogen peroxide (H₂O₂), de-ionized water, and/or other chemicals. A portion of the etch stop layer 3 is removed so as to allow a later-to-be-formed plug to make electrical contact with metal layer 2. Etch stop layer 3 may be removed by various suitable etching methods available in the art.

The trench opening 14 and via hole 16 are then filled with a plug or conductive material 18 thereby forming a dual damascene structure as shown in FIG. 6 according to one embodiment of the present invention. The conductive material 18 may be formed by PVD, CVD, PECVD, ALD, PDL, spin-on coating, and/or other processing techniques. The conductive material 18 may include single and/or multiple layers of conductive material. For example, the conductive material 18 may include a barrier layer and bulk filling material. The barrier layer may include titanium (Ti), tungsten nitride (WN), silicon carbide (SiC), silicon oxy-carbide (SiOC), and/or other materials. The bulk filling material may include aluminum (Al), copper (Cu), gold (Au), silver (Ag), carbon nano-tubes, and/or other materials. Following formation of the plug, the damascene structure may then be polished using CMP for example to planarize the wafer surface and prepare the surface for formation of another layer or level in a multi-layered semiconductor device. The above processing steps may be repeated to form multiple levels of interconnects.

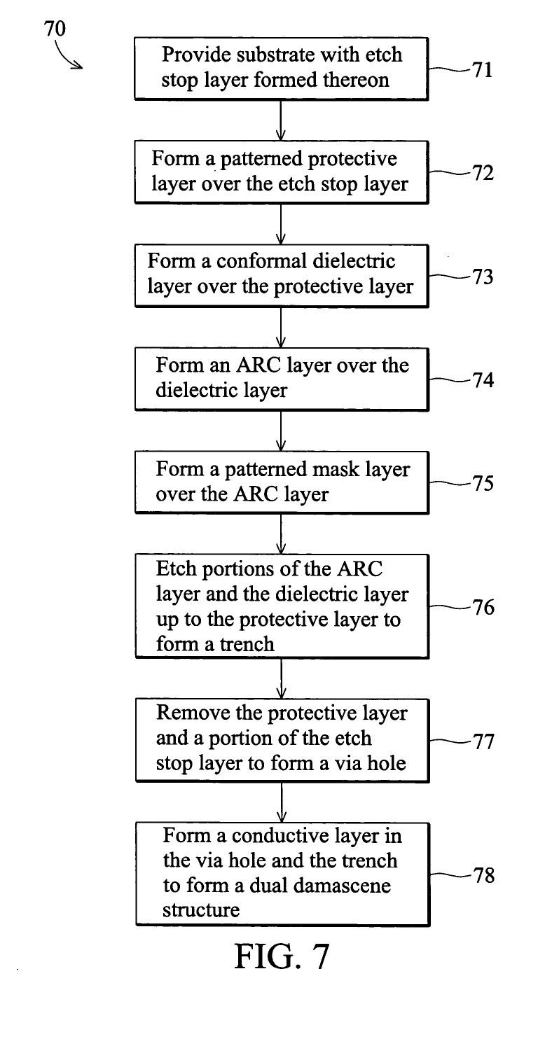

FIG. 7 is a flow chart of a method for forming a dual damascene structure according to one aspect of the present invention. The method 70 begins at step 71 in which a substrate is provided with an etch stop layer formed thereover. At step 72, a patterned protective layer is formed over the etch stop layer. At step 73, a conformal dielectric layer is formed over the protective layer. At step 74, an ARC layer is formed over the dielectric layer. At step 75, a patterned mask layer is formed over the ARC layer. At step 76, portions of the ARC layer and the dielectric layer are etched to form a trench. At step 77, the protective layer and a portion of the etch stop layer are removed to form a via hole. At step 78 of method 70, a conductive layer is formed in the via hole and trench to form a dual damascene structure.

The present disclosure introduces a damascene process utilized in semiconductor manufacturing that uses far fewer processing steps when compared to conventional dual damascene methodologies. By employing the damascene process of the present invention lower process and tool costs can be realized along with damascene structures that exhibit good RC uniformity and low K values.

In the preceding detailed description, the present invention is described with reference to specifically exemplary embodiments thereof. It will, however, be evident that various modifications, structures, processes, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

1. A method of forming a semiconductor device, comprising:
providing a semiconductor substrate comprising a first conductive layer overlying the substrate;
forming a protective layer over the substrate;
patterning the protective layer, wherein a footprint of the patterned protective layer substantially superposes the first conductive layer:
forming a conformal dielectric layer over the patterned protective layer and on the sidewalls of the patterned protective layer after the protective layer is patterned;
forming a patterned mask layer over the dielectric layer;
etching a portion of the dielectric layer substantially up to about the top surface of the patterned protective layer according to the pattern of the mask layer to form a trench;
removing the patterned protective layer to form a via hole; and
forming a second conductive layer in the via hole and the trench, thereby forming a dual damascene structure.

2. The method of claim 1, wherein the protective layer comprises polymer.

3. The method of claim 1, wherein the protective layer comprises a photoresist material.

4. The method of claim 1, wherein the protective layer comprises a dielectric material.

5. The method of claim 4, wherein the dielectric material is a low-k dielectric.

6. The method of claim 1, wherein the protective layer comprises an etch selectivity different from the etch selectivity of the dielectric layer.

7. The method of claim 1, wherein the protective layer comprises a low etching rate material, as compared to the dielectric layer.

8. The method of claim 1, wherein the protective layer has a thickness of from about 10 A to about 8000 A.

9. The method of claim 1, further comprising forming a stop layer between the protective layer and the semiconductor substrate.

10. The method of claim 9, wherein the stop layer comprises nitride.

11. The method of claim 1, further comprising forming an anti-reflective coating layer over the dielectric layer prior to the step of forming the patterned mask layer.

12. The method of claim 1, wherein the patterned mask layer comprises photoresist.

13. The method of claim 1, further comprising removing the patterned mask layer.

14. A method of forming a semiconductor device, comprising:
providing a semiconductor substrate, comprising a first conductive layer overlying the substrate, with a stop layer formed on the substrate and the first conductive layer;
forming a protective layer over the stop layer;
patterning the protective layer, wherein a footprint of the patterned protective layer substantially superposes the first conductive layer:
forming a conformal dielectric layer over the patterned protective layer and on the sidewalls of the patterned protective layer after the protective layer is patterned;
forming an anti-reflective coating layer over the dielectric layer;
forming a patterned mask layer over the anti-reflective coating layer;
etching portions of the anti-reflective coating layer and the dielectric layer substantially up to about the top surface of the patterned protective layer according to the pattern of the mask layer to form a trench;
removing the patterned protective layer and a portion of the stop layer to form a via hole; and
forming a second conductive layer in the via hole and the trench, thereby forming a dual damascene structure.

15. The method of claim 14, wherein the protective layer comprises polymer.

16. The method of claim 14, wherein the protective layer comprises a photoresist material.

17. The method of claim 14, wherein the protective layer comprises a dielectric material.

18. The method of claim 17, wherein the dielectric material is a low-k dielectric.

19. The method of claim 14, wherein the protective layer comprises an etch selectivity different than the etch selectivity of the dielectric layer.

20. The method of claim 14, wherein the protective layer comprises a low etching rate material, as compared to the dielectric layer.

21. The method of claim 14, wherein the protective layer has a thickness of from about 10 A to about 8000 A.

22. The method of claim 14, further comprising removing the patterned mask layer and the anti-reflective coating layer.

23. A method of forming a damascene structure, comprising:
providing a semiconductor substrate, comprising a first conductive layer overlying the substrate with a stop layer formed thereon on the substrate and the first conductive layer;
forming a protective layer over the stop layer;
patterning the protective layer, wherein a footprint of the patterned protective layer substantially superposes the first conductive layer:
forming a conformal dielectric layer over the protective layer and on the sidewalls of the patterned protective layer after the protective layer is patterned;
forming an anti-reflective coating layer over the dielectric layer;
forming a patterned mask layer over the anti-reflective coating (ARC) layer;
etching portions of the anti-reflective coating layer and the dielectric layer substantially up to about the top surface of the patterned protective layer according to the pattern of the mask layer to form a trench;
removing the patterned protective layer and a portion of the stop layer to form a via hole;
forming a second conductive layer in the via hole and the trench, thereby forming a dual damascene structure.

24. A method of making an interconnect structure, comprising:
providing a semiconductor substrate, comprising a metal layer overlying the substrate, with a stop layer formed on the substrate and the metal layer;
forming a protective layer over the stop layer;
patterning the protective layer, wherein a footprint of the patterned protective layer completely superposes the metal layer:
forming a conformal dielectric layer over the protective layer and on sidewalls of the patterned protective layer after the protective layer is patterned;
forming an anti-reflective coating layer over the dielectric layer;
forming a patterned mask layer over the anti-reflective coating layer;
etching portions of the anti-reflective coating layer and the dielectric layer substantially up to about the top surface of the patterned protective layer according to the pattern of the mask layer to form a trench;
removing the patterned protective layer and a portion of the stop layer to form a via hole;
forming a conductive layer in the via hole and the trench, thereby forming a dual damascene structure,
